(19) United States
(12) Patent Application Publication
(10) Pub. No.: US 2009/0164152 A1
(43) Pub. Date: Jun. 25, 2009

(54) Method, Apparatus and Computer Program Product for Providing Power Consumption Notification and Management

(75) Inventors: Gerard Bosch Creus, Helsinki (FI); Petri Otto Kalevi Niska, Helsinki (FI); Mika Kuulusa, Helsinki (FI); Jaakko Henrikki Kyro, Helsinki (FI); Juan Feng, Espoo (FI); Tanya Widen, Hampstead (GB); Juha Henrik Arrasvuori, Tampere (FI); Christian Rossing Kraft, Frederiksberg (DK); Peter Dam Nielsen, Lyngby (DK); Lauri Samuli Aarnio, Espoo (FI); Ismo Juhani Lippojoki, Vantaa (FI)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Nokia Corporation

(21) Appl. No.: 11/961,602

(22) Filed: Dec. 20, 2007

(51) Int. Cl. G01R 31/36

(52) U.S. Cl. 702/63

(57) ABSTRACT

A method, apparatus and computer program product are provided for providing power consumption notification and management. More particularly, application power consumption models and device battery energy levels can be used to determine a device discharge duration. A device power consumption rate can be determined from application power consumption models.

### TECHNOLOGICAL FIELD

Embodiments suspended of the present invention relate generally to power consumption, and more particularly, relate to a method, apparatus and computer program for providing power consumption notification and management on electronic devices.

### BACKGROUND

The modern communications era has brought about a tremendous expansion of wireline and wireless networks. Computer networks, television networks, and telephony networks are experiencing an unprecedented technological expansion, fueled by consumer demand. Wireless and mobile networking technologies have addressed related consumer demands, while providing more flexibility and immediacy of information transfer.

This explosive growth of mobile communications networks has followed the evolution of mobile devices, such as cellular phones, personal digital assistants (PDAs), and other portable electronic devices from luxury items to ubiquitous devices integrated into the everyday lives of individuals from all walks of life. The widespread adoption of mobile devices, and the expanding capabilities of the wireless networks over which they communicate, has allowed for a tremendous expansion in the applications which mobile devices are capable of executing. In addition to providing for phone service, many mobile devices now execute applications such as navigation services through the use of GPS, camera and video capturing, digital music and video playback, and web browsing.

While this expansion in the applications of mobile devices has been revolutionary, the added applications do have a drawback in that the power consumption of mobile devices is increasing rapidly while power storage capacity of mobile devices, i.e. the power storage capacity of batteries, is remaining constant or increasing at a relatively slower pace. In this regard, each added application can be associated with an increase in power consumption by the mobile device. For example, a camera application with a flash or GPS receiver may consume a relatively substantial amount of energy. The increased and variable power consumption associated with these added applications can present problems to users in that users can no longer effectively predict the length of time associated with a fully charged battery. Since users typically think of the discharge of a battery in terms of time, i.e. a discharge time, rather than in terms of power consumption, users are frequently caught in situations where they have unexpectedly discharged the power stored in a battery. These problems can be particularly troublesome for device users when they are in situations where alternate power sources are unavailable to charge the mobile device battery or otherwise power the mobile device. As a result, utilization of these additional applications can leave an unsuspecting user with a substantially useful mobile device, but no power to operate the device.

Additionally, conventional power monitoring and management solutions on mobile devices have become obsolete in light of the additional applications that mobile devices are now implementing. Typically, current mobile devices utilize an indicator that conveys to the user the energy remaining in the battery. Often the quantity of energy is associated with a series of bars or a percentage depicted on a display. While these conventional indicators inform a user of the energy remaining in the battery, the indicators do not inform the user of the rate at which the user is expending the remaining energy.

Further, in some instances in which multiple applications with high power consumption are executed concurrently, an amount of current may be drawn from the battery that is sufficient to cause a voltage decrease. In extreme cases, current consumption may cause the voltage to drop below a cut-off value, which may cause a shut down of the device. Further, in some instances, the rapid discharge of a battery due to high power consumption can cause significant heating of the battery and can lead to damage to the device and its components, discomfort to the user, etc.

Furthermore, unmanaged power consumption by mobile devices can have impacts on the environment. Production of the energy used to charge mobile device batteries can result in pollution, such as from the burning of fossil fuels, as well as depletion of non-renewable energy resources. Furthermore, disposal of spent mobile device batteries, which may contain toxic compounds, may also result in problematic environmental impacts.

Accordingly, it would be advantageous to provide methods, apparatuses, and computer program products that provide for managing power consumption within mobile devices and, as such, prolonging the discharge time of a mobile device.

### BRIEF SUMMARY

A method, apparatus and computer program product are therefore provided that allow for power consumption notification and management. In particular, at least one application power consumption model and a device battery energy level can be received. A device discharge duration can be determined using the at least one application power consumption model and the battery energy level. In some embodiments, application power consumption models can be generated from historical power consumption data captured during one or more prior implementations of an application.

In some embodiments, a standby discharge duration can be received. A notification can be provided based on a result of comparing the standby discharge duration to the device discharge duration. Further, in some embodiments, a device power consumption rate can be determined from the at least one application power consumption model. In some embodiments, a notification can be provided as a result of comparing the device power consumption rate with a threshold rate. In some embodiments, a selection of applications to suspend can be provided based on a result of comparing the device power consumption rate with a threshold rate.

### BRIEF DESCRIPTION OF THE SEVERAL VIEWS OF THE DRAWING(S)

Having thus described embodiments of the invention in general terms, reference will now be made to the accompanying drawings, which are not necessarily drawn to scale, and wherein:

FIG. 1 is a schematic block diagram of a mobile terminal according to an embodiment of the present invention;

FIG. 2 is a schematic block diagram of an energy and power management module according to an embodiment of the present invention;

FIG. 3 is a flow chart of a power management method according to an embodiment of the present invention;

FIG. 4 is a signaling diagram of a power management procedure according to an embodiment of the present invention;

FIG. 5a is an illustration of a display of a mobile terminal including energy and power management information according to an embodiment of the present invention;

FIG. 5b is an illustration of a display of a mobile terminal including energy and power management information according to an embodiment of the present invention;

FIG. 6a is an illustration of a display of a mobile terminal including energy and power management information according to an embodiment of the present invention;

FIG. 6b is an illustration of a display of a mobile terminal including energy and power management information according to an embodiment of the present invention; and

FIG. 7 is an illustration of a display of a mobile terminal including energy and power management information according to an embodiment of the present invention.

### DETAILED DESCRIPTION

Embodiments of the present invention will now be described more fully hereinafter with reference to the accompanying drawings, in which some, but not all embodiments of the invention are shown. Indeed, the invention may be embodied in many different forms and should not be construed as limited to the embodiments set forth herein; rather, these embodiments are provided so that this disclosure will satisfy applicable legal requirements. Like reference numerals refer to like elements throughout.

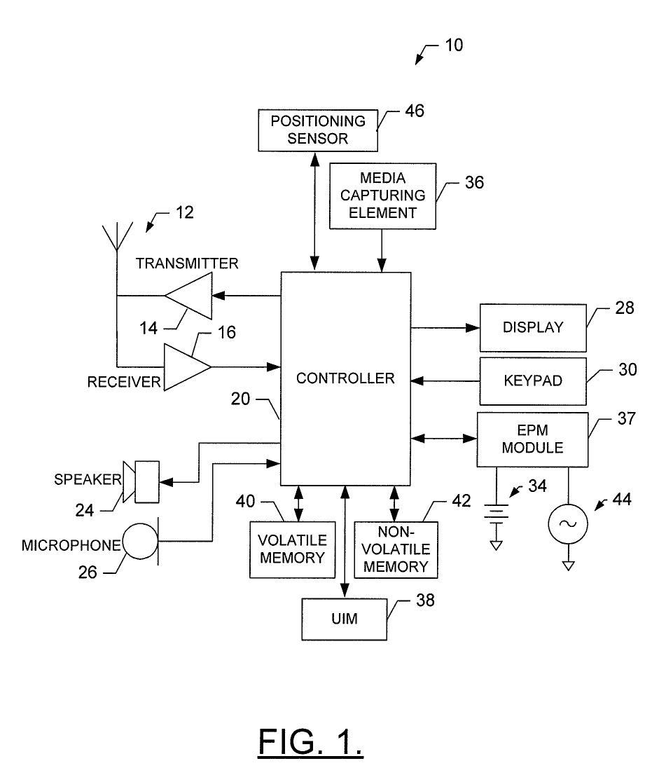

FIG. 1 illustrates a block diagram of a mobile terminal 10 that may benefit from embodiments of the present invention. It should be understood, however, that a mobile telephone as illustrated and hereinafter described is merely illustrative of one type of mobile terminal that may benefit from embodiments of the present invention and, therefore, should not be taken to limit the scope of embodiments of the present invention. While one embodiment of the mobile terminal 10 is illustrated and will be hereinafter described for purposes of example, other types of mobile terminals, such as portable digital assistants (PDAs), pagers, mobile computers, mobile televisions, gaming devices, laptop computers, cameras, video recorders, GPS devices and other types of voice and text communications systems, can readily employ embodiments of the present invention. Furthermore, devices that are not mobile may also readily employ embodiments of the present invention.

Embodiments of the present invention will be primarily described below in conjunction with mobile communications applications. However, it should be understood that the embodiments of the present invention can be utilized in conjunction with a variety of other applications, both in the mobile communications industries and outside of the mobile communications industries.

The mobile terminal 10 includes an antenna 12 (or multiple antennae) in operable communication with a transmitter 14 and a receiver 16. The mobile terminal 10 further includes a processor, such as a controller 20 or other processing element or computing device, that provides signals to and receives signals from the transmitter 14 and receiver 16, respectively. The signals include signaling information in accordance with the air interface standard of the applicable cellular system, and also user speech, received data and/or user generated data. In this regard, the mobile terminal 10 is capable of operating with one or more air interface standards, communication protocols, modulation types, and access types. By way of illustration, the mobile terminal 10 is capable of operating in accordance with any of a number of first, second, third and/or fourth-generation communication protocols or the like. For example, the mobile terminal 10 may be capable of operating in accordance with second-generation (2G) wireless communication protocols IS-136 (time division multiple access (TDMA)), GSM (global system for mobile communication), and IS-95 (code division multiple access (CDMA)), or with third-generation (3G) wireless communication protocols, such as Universal Mobile Telecommunications System (UMTS), CDMA2000, wideband CDMA (WCDMA) and time division-synchronous CDMA (TD-SCDMA), with fourth-generation (4G) wireless communication protocols or the like.

Additionally, mobile terminal 10 can implement various other communications techniques. For example, mobile terminal 10 may use radio frequency (RF), Bluetooth (BT), infrared (IrDA) or any of a number of different wireless networking techniques, including wireless LAN (WLAN) techniques such as IEEE 802.11 (e.g., 802.11a, 802.11b, 802.11g, 802.11n, etc.), world interoperability for microwave access (WiMAX) techniques such as IEEE 802.16, Wibree, ZigBee IEEE 802.15.4, and/or ultra wideband (UWB) techniques such as IEEE 802.15 and/or the like. Mobile terminal 10 can use these techniques to communicate directly with other mobile devices, such as other mobile terminals, headsets, GPS devices, PDAs, pagers, mobile computers, mobile televisions, gaming devices, laptop computers, cameras, video recorders or indirectly through access points on a communications network.

It is understood that the apparatus such as the controller 20 includes means, such as circuitry, desirable for implementing audio and logic functions of the mobile terminal 10. For example, the controller 20 may be comprised of a digital signal processor device, a microprocessor device, and various analog to digital converters, digital to analog converters, and other support circuits. Control and signal processing functions of the mobile terminal 10 are allocated between these devices according to their respective capabilities. The controller 20 thus may also include the functionality to convolutionally encode and interleave message and data prior to modulation and transmission. The controller 20 can additionally include an internal voice coder, and may include an internal data modem. Further, the controller 20 may include functionality to operate one or more software programs, which may be stored in memory. For example, the controller 20 may be capable of operating a connectivity program, such as a conventional Web browser. The connectivity program may then allow the mobile terminal 10 to transmit and receive Web content, such as location-based content and/or other web page content, according to a Wireless Application Protocol (WAP), Hypertext Transfer Protocol (HTTP) and/or the like, for example.

The mobile terminal 10 may also comprise a user interface including an output device such as a conventional earphone or speaker 24, a microphone 26, a display 28, and a user input interface, all of which are coupled to the controller 20. The user input interface, which allows the mobile terminal 10 to receive data, may include any of a number of devices allowing the mobile terminal 10 to receive data, such as a keypad 30, a touch display (not shown) or other input device. In embodiments including the keypad 30, the keypad 30 may include the conventional numeric (0-9) and related keys (#, *), and other hard and/or soft keys used for operating the mobile terminal 10. Alternatively, the keypad 30 may include a conventional QWERTY keypad arrangement. The keypad 30 may also include various soft keys with associated functions. In addition, or alternatively, the mobile terminal 10 may include an interface device such as a joystick or other user input interface.

The mobile terminal 10 further includes a battery 34, such as a vibrating battery pack, for powering various circuits that are required to operate the mobile terminal 10, as well as optionally providing mechanical vibration as a detectable output. Battery 34 can provide power directly to mobile terminal 10 or indirectly through power control module 37. Additionally, mobile terminal 10 can be powered through power control module 37 by supplemental power source 44. Supplemental power source 44 can be any power source that is not the primary power source of mobile terminal 10. Further, supplemental power source 44 can take various forms including, but not limited to a power adapter electrically connected to a wall outlet or other electrical outlet, in for example, a vehicle or airplane. In this regard, supplemental power source 44 can be removable from mobile terminal 10 to permit unfettered mobility of mobile terminal 10. When supplemental power source 44 is removed, or disconnected, either physically or electrically, for instance through functionality in energy and power management module 37, battery 34 can be the sole power source of mobile terminal 10.

In some embodiments, the mobile terminal 10 can include a media capturing element 36, such as a camera, video and/or audio module, in communication with the controller 20. The media capturing element 36 may be any means for capturing an image, video and/or audio for storage, display or transmission. For example, in an embodiment in which the media capturing element is a camera module, the camera module may include a digital camera capable of forming a digital image file from an image captured by camera module. As such, the camera module includes all hardware, such as a lens or other optical component(s), and software necessary for creating a digital image file from a captured image. The camera module may also include all hardware, such as a lens or other optical component(s), and software necessary to provide image zooming functionality. Image zooming functionality can include the ability to magnify or de-magnify an image prior to or subsequent to capturing an image. Alternatively, the camera module may include only the hardware needed to view an image, while a memory device of the mobile terminal 10 stores instructions for execution by the controller 20 in the form of software necessary to create a digital image file from a captured image. In an exemplary embodiment, the camera module may further include a processing element such as a co-processor which assists the controller 20 in processing image data and an encoder and/or decoder for compressing and/or decompressing image data. The encoder and/or decoder may encode and/or decode according to, for example, a joint photographic experts group (JPEG) standard or other format.

The mobile terminal 10 may further include a user identity module (UIM) 38. The UIM 38 is typically a memory device having a processor built in. The UIM 38 may include, for example, a subscriber identity module (SIM), a universal integrated circuit card (UICC), a universal subscriber identity module (USIM), a removable user identity module (R-UIM), etc. The UIM 38 typically stores information elements related to a mobile subscriber. In addition to the UIM 38, the mobile terminal 10 may be equipped with memory. For example, the mobile terminal 10 may include volatile memory 40, such as volatile Random Access Memory (RAM) including a cache area for the temporary storage of data. The mobile terminal 10 may also include other non-volatile memory 42, which can be embedded and/or may be removable. The non-volatile memory 42 can additionally or alternatively comprise an electrically erasable programmable read only memory (EEPROM), flash memory or the like, such as that available from the SanDisk Corporation of Sunnyvale, California, or Lexar Media Inc. of Fremont, Calif. The memories can store any of a number of pieces of information, and data, used by the mobile terminal 10 to implement the functions of the mobile terminal 10. For example, the memories can include an identifier, such as an international mobile equipment identification (IMEI) code, capable of uniquely identifying the mobile terminal 10.

In some embodiments, mobile terminal 10 can also include a energy and power management (EPM) module 37, in communication with the controller 20. The EPM module 37 may be any means, hardware or software for managing power within mobile terminal 10. In some embodiments, EPM module 37 can be a software implementation operating on controller 20 of mobile terminal 10. As such, EPM module 37 can include all hardware, and software necessary for managing power within mobile terminal 10. In an example embodiment, EPM module 37 may further include a processing element such as a co-processor which assists the controller 20 in managing power.

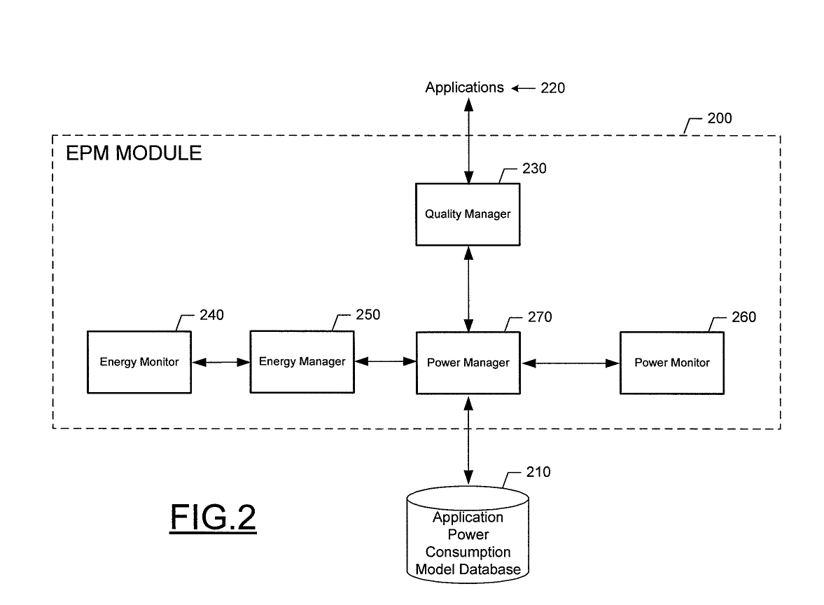

FIG. 2 depicts a schematic block diagram of an EPM module according to an embodiment of the present invention. The schematic block diagram of FIG. 2 includes EPM module 200 in a similar manner to EPM module 37 of FIG. 1. EPM module 200 can be comprised of quality manager 230, energy monitor 240, energy manager 250, power monitor 260, and power manager 270. With respect to the example schematic block diagram of FIG. 2, EPM module 200 can interact with application power consumption model (APCM) database 210 and applications 220, however it is contemplated that EPM module 200 can interact with various other entities including but not limited to controller 20, battery 34 and supplemental power source 44 of FIG. 1. On some embodiments, the communications between the various elements of FIG. 2 can be via application programming interfaces (APIs) within an operating system.

APCM database 210 can be a compilation of data, organized as application power consumption models, that describes the power consumption of various applications that can be implemented by mobile terminal 10. The application power consumption models can be used to predict the power consumption of applications. APCM database 210 can be stored in non-volatile memory 42 of mobile terminal 10. In some embodiments, APCM database 210 can be stored on a remote device, such as a server, and accessed by mobile terminal 10 via the various communications techniques that can be utilized by mobile terminal 10. The APCM database 210 can be pre-loaded into the memory of mobile terminal 10 during manufacturing and/or setup. In this regard, in some embodiments, the models can be generated by running applications on a test platform under various conditions, such as, differing batteries. As such, averages of the power consumption of a particular application can be used to develop a model. In some embodiments, application power consumption models can be generated or updated using actual data gathered from the power usage of mobile terminal 10 when mobile terminal 10 is implementing various applications. In this regard, a history of application power consumption can be stored and utilized to generate or update application power consumption models. As such, the application power consumption models can be constantly improved as a user implements applications on the device. For example, when mobile terminal 10 implements a GPS application using positioning sensor 46, controller 20, EPM module 37, or other means, can monitor and log the power consumption of mobile terminal 10 that can be attributed to the GPS application to generate or update a GPS application power consumption model. Application power consumption models may also include information regarding the timing of power usage when an application is implemented to generate a power consumption time profile. For example, if the GPS application has relatively high power consumption when the application is first implemented, but the power consumption reduces to a lower level at a later time, this information can be considered in generating the application power consumption model. Further, factors outside of the application, describing a use context, can also be considered when generating or updating an application power consumption module. These factors can include, but should not be limited to, such as, but not limited to, the communications signal strength and interactions with other applications which may require the same resources, such as a common communications channel. As such, application power consumption models may consider the relative impacts of resource sharing in the development of the model. Further, the models may also consider the power implications of situations where the requirements of two or more applications conflict with respect to a particular resource. Further, application power consumption models can be dependant upon the type or model of battery utilized.

Applications 220 of FIG. 2 can be applications currently implemented on mobile terminal 10. The applications 220 can be hardware or software applications. For example, applications 220 can include, but are not limited to, a WLAN session implemented in software by controller 20, a video capture implemented in hardware by media capturing element 36, a digital video broadcast-handheld (DVB-H) session implemented in hardware and software, etc. As such, applications can include the implementation of various radios or communications bearers, such as WLAN, or BT, on, for example, mobile terminal 10.

Quality manager 230 of EPM module 200 can gather information regarding the applications 220 currently implemented by mobile terminal 10. Quality manger 230 can be implemented in hardware, software or some combination thereof. In some embodiments where quality manger 230 is implemented in software, quality manager 230 can be part of a operating system and can implemented on, for example controller 230 of mobile terminal 10. Quality manger 230 can receive information regarding what applications are currently implemented on mobile terminal 10, the current state of the applications, i.e. standby or active, and the quality levels of the applications. The quality level of an application can indicate its performance level, e.g. implementation speed or quality of output results, and the related resource consumption. Quality manager 230 can use the information gathered about the currently implemented applications to develop a current use context of mobile terminal 10. Quality manager 230 can also receive requests, initiated by a user or other functionality within mobile terminal 10, to implement additional applications. Additionally, quality manger 230 can provide the information about the applications, or some compiled version of the information about the applications, to power manager 270.

Energy monitor 240 can gather information regarding the power sources of mobile terminal 10, such as battery 34 and supplemental power source 44. Energy monitor 240 can be implemented in hardware, software or some combination thereof. Energy monitor 240 can capture various power source parameters, such as, for example, the voltage levels of the power sources. Energy monitor 240 can provide information regarding power source parameters to energy manager 250.

Energy manager 250 can perform calculations based on the information provided by energy monitor 240. Energy manager 250 can be implemented in hardware, software or some combination thereof. Energy manager 250 may have access to energy attributes of mobile terminal 10, such as, the model of battery powering mobile terminal 10, and various attributes associated with the model of the battery. Energy manager 250 can use the energy attributes and the power source parameters provided by energy monitor 240 to perform energy related calculations. For example, using the voltage levels of a battery provided by energy monitor 240, and the energy attributes associated with the type of battery connected to mobile terminal 10, energy manager 250 can estimate the remaining charge in the battery, that is, the battery energy level. Energy manager 250 can provide the result of the calculations, such as the battery energy level, to power manager 270.

Power monitor 260 can monitor the overall power consumption level on mobile terminal 10. Power monitor 260 can be implemented in hardware, software or some combination thereof. The overall power consumption can be dependant upon variables which may not be accurately modeled, such as the necessary communication signal strength at a given location. Power monitor 260 can provide the overall power consumption level to power manger 270.

Power manager 270 can be an element within EPM module that implements power management functionality using data acquired from various sources, including but not limited to, APCM database 210, quality manager 230, energy manager 250, power monitor 260. For example, power manager 210 can receive information regarding the applications currently implemented on mobile terminal 10 and requests to initiate new applications from quality manager 230. Power manager 270 can use this information to generate a query of the APCM database 210. APCM database 210 can return to power manager 270 the application power consumption models associated with the applications currently implemented on mobile terminal 10 and the new applications that have requested implementation on mobile terminal 10. Power manger 270 can also receive, for example, the battery energy level from energy manager 250 and the current power consumption level from power monitor 260. Power manager 270 can use, for example, the application power consumption models, the battery energy level, and the power consumption level to determine a device discharge duration with respect to one or more applications that have requested implementation. Additionally, using the information provided by various sources, power manager 270 can provide for notification to a user regarding power management and provide for functionality which allows selectively suspending applications that have power consumption demands.

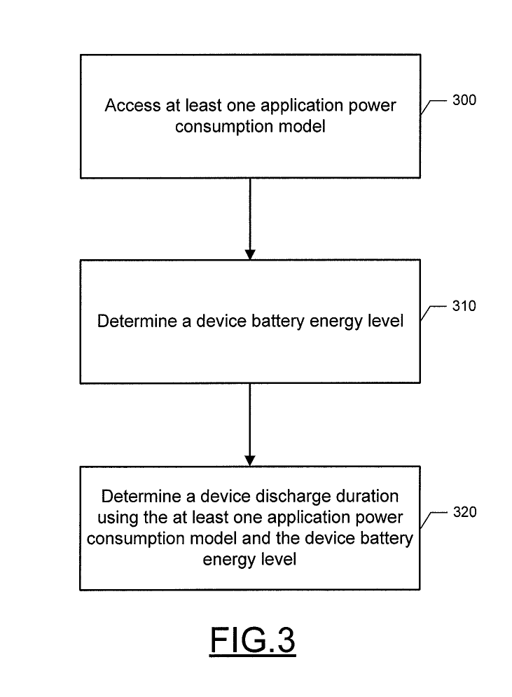

FIG. 3 is a flow chart of a power management method according to an embodiment of the present invention. The method of FIG. 3 can be implemented on for example, EPM module 200, controller 20 of mobile terminal 10, or other means. The method can comprise receiving at least one application power consumption model at 300, receiving a battery energy level at 310, and determining a device discharge duration using the at least one application power consumption model and the battery energy level at 320.

At 300, at least one application power consumption model can be accessed. The at least one application power consumption model can be accessed by power manager 270 of EPM module 200, controller 20 of mobile terminal 10, or other means. The at least one application power consumption model can be accessed from a database, such as APCM database 210, as a result of a query. The application power consumption models that are accessed, can be the application power consumption models associated with applications that are currently being implemented or applications that are requesting implementation.

At 310, a device battery energy level can be determined. The device battery energy level can be determined by, power manager 270 of EPM module 200, controller 20 of mobile terminal 10, or other means. In some embodiments, determining the device battery energy level can comprise receiving the device battery energy level from, for example, energy monitor 240. The device battery energy level can describe the charge remaining within a battery powering, for example, mobile terminal 10. In some embodiments, the device battery energy level can be received from energy manger 250 and can be based on voltage level readings gathered by energy monitor 240.

At 320, a device discharge duration can be determined. The device discharge duration can be determined by power manager 270 of EPM module 200, controller 20 of mobile terminal 10, or other means. The device discharge duration can be determined using at least one application power consumption model and the device battery energy level. In some embodiments, the device discharge duration can be determined using, in addition to at least one application power consumption model and the device battery energy level, an overall power consumption level, provided by, for example, power monitor 260. In some embodiments, the device discharge duration can be a prediction of the remaining time available to a user, given the applications that are currently implemented, until the battery is discharged to a level where the battery can no longer power the device. In some embodiments, the device discharge duration can describe a prediction of the remaining time until the battery is discharged to a level where the battery can no longer power the device, if an application that has recently requested implementation, is implemented. Additionally, in some embodiments, since the device discharge duration is an estimate based on models, a more conservative estimate may be utilized. In other words, as the estimated device discharge duration decreases to relatively short durations, for example, five minutes, the device discharge duration can be further reduced, for example to four minutes, so as to maximize the likelihood that the actual duration to discharge is not less than the estimated device discharge duration.

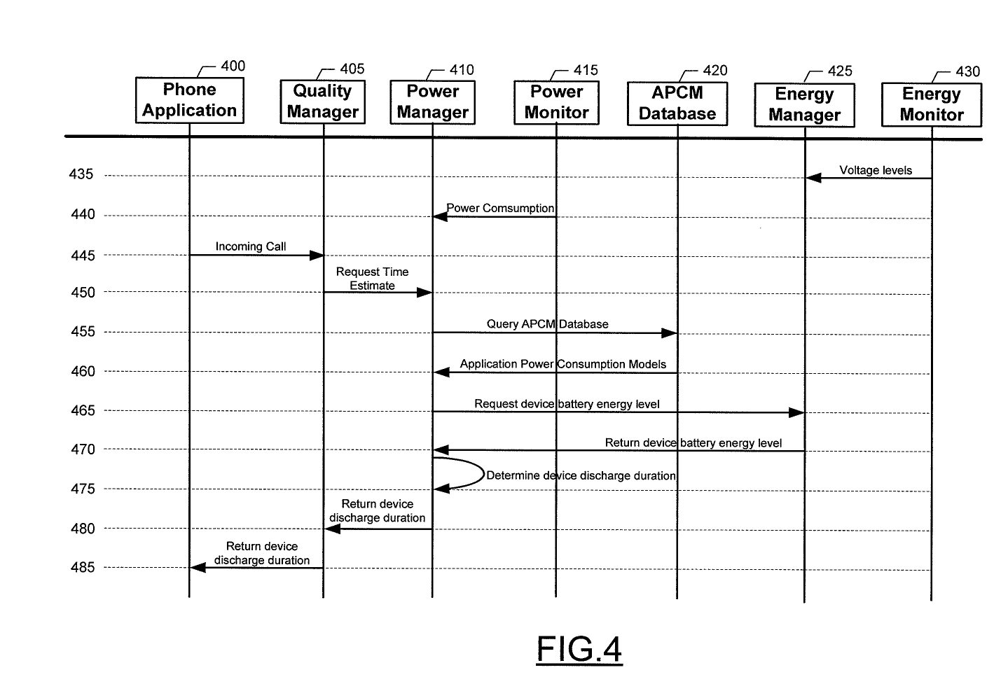

FIG. 4 is an example signaling diagram of a power management procedure according to an embodiment of the present invention where a device discharge duration is determined. The signaling diagram of FIG. 4 describes an example situation where an incoming call is received by, for example, mobile terminal 10. FIG. 4 describes the signaling interactions between phone application 400, quality manager 405, power manger 410, power monitor 415, APCM database 420, energy manager 425, and energy monitor 450. The entities described in the signaling diagram of FIG. 4 can be similar to the entities described with respect to FIG. 2.

At 435, energy monitor 430 can send voltage levels of a battery to energy manager 425. At 440, according to some embodiments, power monitor 415 can send an overall power consumption value to power manager 410. In some embodiments, the operations of 435 and 440 can be repeated at regular or irregular intervals. At 445, phone application 400 informs quality manager 405 that an incoming call has been received. Quality manager 405 then sends application information regarding the applications that are currently implemented, information about the phone application, and a request to power manager 410 for a device discharge duration at 450. At 455, power manager 410 queries the APCM database 420 for the currently implemented application power consumption models, including the phone application model. At 460, APCM 420 returns the currently implemented application power consumption models, including the phone application model. At 465, power manager 410 requests the device battery energy level from energy manager 425. Power manager 410 then receives the device battery energy level from energy manager 425, at 470. At 475, power manager 410 can use the application power consumption models, the device battery energy level, and, in some embodiments, the overall power consumption level, to determine the device discharge duration. Power manager 410 can then send the device discharge duration to quality manager 405, at 480. Quality manager 405 can then send the device discharge duration to phone application 400, at 485, to be used for, for example, notifying a user of the device discharge duration. This can allow the user to make an informed decision as to whether to take the call, or if the user takes the call, it can inform the user how long the use has to complete the call.

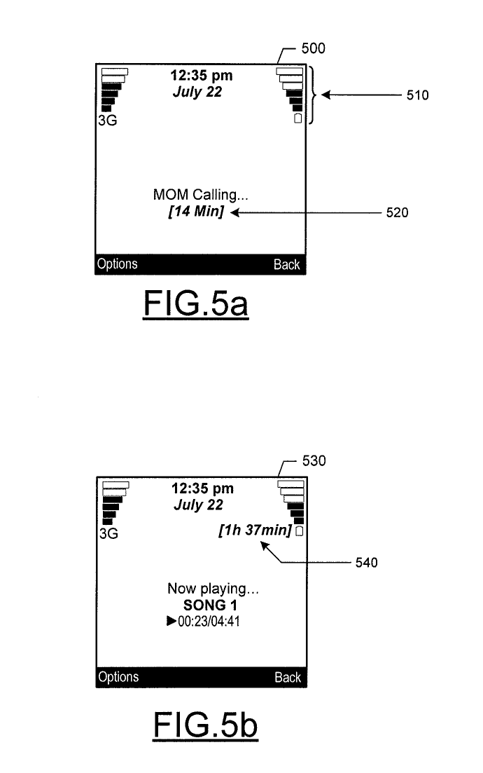

Various embodiments can provide for a notification or implementation of particular actions based on the device discharge duration. For example, a user may be notified of the device discharge duration by providing for the display of the device discharge duration on, for example, display 28 of mobile terminal 10. FIGS. 5a and 5b depict example mobile device displays where a display of the device discharge duration is provided for by, for example, power manager 270 of EPM module 200, controller 20 of mobile terminal 10, or other means. FIG. 5a depicts a display that could describe the result of the operations described with respect to FIG. 4 where an incoming call is being received. FIG. 5a includes a display 500, a power indicator 510, and device discharge duration indicator 520. As depicted in display 500, the device is receiving an incoming call. As a result of, for example, the operations of FIG. 4, the device discharge duration can be displayed at 520. In this regard, the device discharge duration indicator 520 informs the user that if the call is taken, the user will have fourteen minutes of call time before the battery can no longer power the device. In some embodiments, the device discharge duration can be divided such that notification provides that after a first duration of call time, a second duration of standby time will remain. Further, according to some embodiments, power indicator 510 can display of the device battery energy level.

FIG. 5b depicts a similar situation including display 530 and device discharge duration indicator 540. With respect to example FIG. 5b, a device is implementing various applications including an audio playback application. However, as discussed above, embodiments of the present invention can be applicable to any application presently implemented or requesting to be implemented on a device. According to various embodiments of the invention, the display 530 can include a device discharge duration indicator 540. Device discharge duration indicator 540 can describe the time remaining for the battery to support the audio playback application, in addition to any other applications that are running but are not depicted on display 530. Further, in some embodiments, the device discharge duration can be divided between applications. In this regard, a notification can be provided indicating, for example, the standby time that will remain after the current song is finished playing.

In some embodiments, based on the device discharge duration, a user can define how the user prefers to be notified. For example, a user may prefer that a vibrating battery action be implemented when the device discharge duration reaches a predefined level. Additionally, the display of a device discharge duration may change color based on the device discharge duration. Further, in some embodiments, when the device discharge duration reaches a predefined level, a predefined set of applications can be suspended, such that the applications can no longer consume energy resources. Further, in some embodiments, since power consumption information can be utilized at the application level, notification of power consumption information can be displayed at the application level.

In some embodiments, based on the received application power consumption models and, in some embodiments, the overall power consumption level, a power consumption rate can be determined. The power consumption rate can be determined by power manager 270 of EPM module 200, controller 20 of mobile terminal 10, or other means. Similarly, with the use of the application power consumption models, portions of the power consumption rate that are attributed to particular applications can also be defined. The power consumption rate can be the rate at which power is being depleted from, for example, a battery. In some embodiments, the power consumption rate can be used to notify the user of, for example, a high power consumption condition, or to implement power management functionality. For example, in some embodiments, ranges of power consumption can be defined, such as, low, medium, and high. When the power consumption rate of a device is located within a particular range, a notification can be provided. In some embodiments, a power indicator, such as the power indicator 510 of FIG. 5a, can change color based on the range where the power consumption rate falls. The color can be changed by power manager 270 of EPM module 200, controller 20 of mobile terminal 10, or other means.

In some embodiments, power management can be performed with regard to supplemental devices. Supplemental devices can be any device that works in conjunction with another device, but is powered by a separate power source. For example, a GPS device or wireless headset having a separate battery that communicates to a mobile terminal via, for example, Bluetooth, can be a supplemental device. Further, in some embodiments, the applications of a supplemental device can have associated application power consumption models stored in, for example, APCM 210 of FIG. 3. According to various embodiments, a supplemental device battery energy level can be received by power manager 270 of EPM module 200, controller 20 of mobile terminal 10, or other means. In some embodiments, supplemental device power consumption levels can also be received by power manager 270 of EPM module 200, controller 20 of mobile terminal 10, or other means. Using the application power consumption models and the supplemental device battery energy levels, a supplemental device power consumption rate can be determined. In some embodiments, the supplemental device power consumption rates can be determined using the supplemental power device consumption levels, in addition to the application power consumption models and the supplemental device battery energy levels. As a result, power manager 270 of EPM module 200, controller 20 of mobile terminal 10, or other means can provide for the display of supplemental device power consumption rates on, for example, display 28 of mobile terminal 10. Referring to FIG. 5a, in some embodiments, power indicator 510 can alternate between depicting a display of the device battery energy level, the device consumption rate, one or more supplemental device battery levels, or one or more supplemental device consumption rates. In some embodiments, a device charge duration of a battery connected to charger can be determined by any known means. In this regard, power indicator 510 can also alternate to a depiction of the device charge duration. Further, in some embodiments, a power indicator may alternate based on the values associated with the various parameters. For example if device battery energy level is relatively low, the alternation may depict the device battery energy level more frequently, or even constantly.

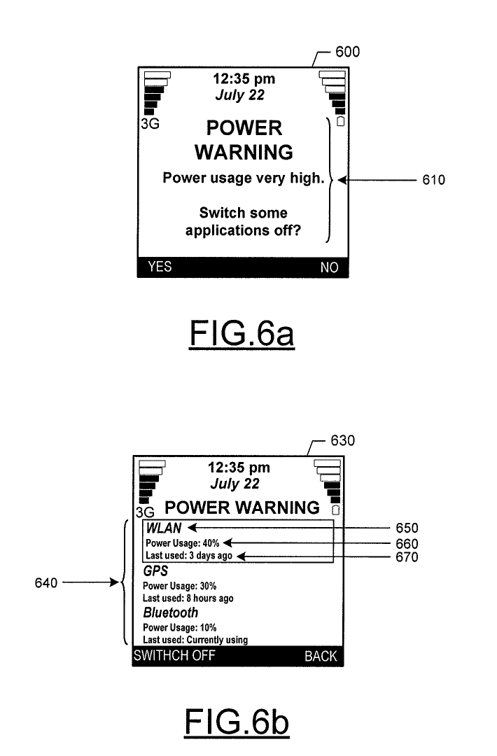

Additionally, in some embodiments, a threshold consumption rate can be defined. In some embodiments, the threshold consumption rate can be user defined or the threshold consumption rate can be defined based on the device battery energy level. In either case, the threshold consumption rate can be compared to the device power consumption rate. If the device power consumption rate exceeds the threshold rate, a notification can be provided. In some embodiments, the device battery energy level, the threshold consumption rate, and/or the device power consumption rate can be considered in determining whether to implement a notification or other action. FIG. 6a depicts an example display 600 including a power consumption rate threshold notification 610. In some embodiments, whether or not the notification is provided can be predefined in a setup operation.

Further in some embodiments, when the threshold consumption rate is exceeded, a selection of currently running applications to suspend can be provided. The selection of currently running applications to suspend can be provided by power manager 270 of EPM module 200, controller 20 of mobile terminal 10, or other means. In some embodiments, a user can initiate a selection of currently running applications to suspend, without regard to the threshold. FIG. 6b depicts an example display 630 where applications can be selected to suspend. The display 630 can include a currently running applications list 640, and for each running application, an application name 650, an application power usage 660, and a utilization time 670. In some embodiments, a user can move through the currently running applications list 640 to select an application to suspend. The power usage 660 for a particular application can indicate the portion of the power consumption rate that is attributed to the particular application. As such, the power usage 660 can indicate to a user the relative power consumption that will be released by suspending the associated application. Further, the utilization time 670 can indicate to user the last time a particular application was utilized. In this regard, it can be common that applications are running in the background, but are not being actively utilized by the user. As such, applications that have not been utilized for a long period of time may be good candidates for suspension. As such, when an application is selected for suspension, power manager 270 of EPM module 200, controller 20 of mobile terminal 10, or other means, can end implementation of the application.

With regard to providing a notification or inviting a user to select currently running applications to suspend, in some embodiments, an average time between charging cycles of a device battery can be considered. The average time can be used as an estimated time to the next charge. For example, if according to the estimated time to next charge, the device is likely to be charged within the next few minutes, a power consumption rate notification may not be implemented. In some embodiments, the estimated time to next charge may be considered in conjunction with the device battery energy level and the power consumption rate to determine if a notification or an invitation to select currently running applications to suspend should be implemented.

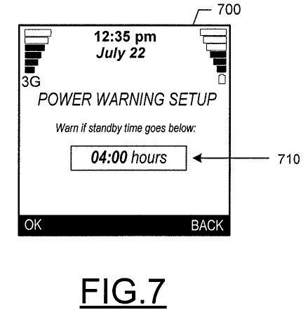

Further, in some embodiments, a user can define a standby discharge duration as depicted in FIG. 7. FIG. 7 includes a display 700 and a standby discharge duration field 710 where a user can set a particular standby discharge duration. In some embodiments, the standby discharge duration can be set automatically by considering the estimated time to next charge. The standby discharge duration can be received by power manager 270 of EPM module 200, controller 20 of mobile terminal 10, or other means. The standby discharge duration can be a duration of time, such that when the device discharge duration falls below the standby discharge duration, a notification can be provided. In this regard, in some embodiments the standby discharge duration may not be associated with standby time, but rather any application, such as, for example, call time, audio playback time or DVB-H session time. Accordingly, a notification such as a warning can be provided, or an opportunity to select applications to suspend, as discussed above, can be presented. A notification can be provided, or an opportunity to select applications to suspend can be provided by power manager 270 of EPM module 200, controller 20 of mobile terminal 10, or other means. In some embodiments, predetermined applications can automatically be suspended when the device discharge duration falls below the standby discharge duration.

According to one aspect of the present invention, the electronic device, such as mobile terminal 10, and more particularly controller 20, which implements embodiments of the present invention generally operates under control of a computer program product. The computer program product for performing the methods of embodiments of the present invention includes a computer-readable storage medium and computer-readable program code portions, such as a series of computer instructions, embodied in the computer-readable storage medium.

In this regard, FIG. 3 is a flowchart of method, apparatus and program products according to exemplary embodiments of the present invention. It will be understood that each block or step of the flowchart, and combinations of blocks in the flowchart, can be implemented by computer program instructions. These computer program instructions may be loaded onto a computer or other programmable apparatus, such as controller 20, to produce a machine, such that the instructions which execute on the computer or other programmable apparatus create means for implementing the functions specified in the flowchart block(s) or step(s). These computer program instructions may also be stored in a computer-readable memory that can direct a computer or other programmable apparatus to function in a particular manner, such that the instructions stored in the computer-readable memory produce an article of manufacture including instruction means which implement the function specified in the flowchart block(s) or step(s). The computer program instructions may also be loaded onto a computer or other programmable apparatus to cause a series of operational steps to be performed on the computer or other programmable apparatus to produce a computer implemented process such that the instructions which execute on the computer or other programmable apparatus provide steps for implementing the functions specified in the flowchart block(s) or step(s).

Accordingly, blocks or steps of the flowchart support combinations of means for performing the specified functions, combinations of steps for performing the specified functions and program instruction means for performing the specified functions. It will also be understood that each block or step of the flowchart, and combinations of blocks or steps in the flowchart, can be implemented by special purpose hardware-based computer systems which perform the specified functions or steps, or combinations of special purpose hardware and computer instructions.

Many modifications and other embodiments of the inventions set forth herein will come to mind to one skilled in the art to which these inventions pertain having the benefit of the teachings presented in the foregoing descriptions and the associated drawings. Therefore, it is to be understood that the embodiments of the invention are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. A method comprising:
accessing at least one application power consumption model;
determining a device battery energy level; and
determining a device discharge duration using the at least one application power consumption model and the battery energy level.

2. The method of claim 1 wherein accessing at least one application power consumption model comprises accessing at least one application power consumption model comprising information generated from historical power consumption data from one or more prior implementations of an application.

3. The method of claim 1 further comprising:
receiving a standby discharge duration; and
providing for a notification based on a result of comparing the standby discharge duration to the device discharge duration.

4. The method of claim 1 further comprising determining a device power consumption rate from the at least one application power consumption model.

5. The method of claim 4 further comprising providing for a notification based on a result of comparing the device power consumption rate with a threshold rate.

6. The method of claim 4 further comprising providing for a selection of applications to suspend based on a result of comparing the device power consumption rate with a threshold rate.

7. The method of claim 4 further comprising providing for a display of a device consumption rate indicator, wherein the display of the device consumption rate indicator changes color based on the device power consumption rate.

8. The method of claim 4 further comprising
accessing at least one supplemental device battery energy level;
determining at least one supplemental device power consumption rate from the at least one application power consumption model; and
providing for a display of a power indicator, wherein the display of the power indicator alternates between an indication of at least two of the device battery energy level, the device consumption rate, a device charge duration, the at least one supplemental device battery level, and the at least one supplemental device power consumption rate.

9. A computer-readable storage medium having computer-readable program code portions stored therein, the computer-readable program code portions comprising:
a first executable portion configured to access at least one application power consumption model;
a second executable portion configured to determine a device battery energy level; and
a third executable portion configured to determine a device discharge duration using the at least one application power consumption model and the battery energy level.

10. The computer-readable storage medium of claim 9 wherein the first executable portion is further configured to access at least one application power consumption model comprising information generated from historical power consumption data from one or more prior implementations of an application.

11. The computer-readable storage medium of claim 9 further comprising
a fourth executable portion configured to receive a standby discharge duration; and
a fifth executable portion configured to provide for a notification based on a result of comparing the standby discharge duration to the device discharge duration.

12. The computer-readable storage medium of claim 9 further comprising a fourth executable portion configured to determine a device power consumption rate from the at least one application power consumption model.

13. The computer-readable storage medium of claim 12 further comprising a fifth executable portion configured to provide for a notification based on a result of comparing the device power consumption rate with a threshold rate.

14. The computer-readable storage medium of claim 12 further comprising a fifth executable portion configured to provide for a selection of applications to suspend based on a result of comparing the device power consumption rate with a threshold rate.

15. The computer-readable storage medium of claim 12 further comprising a fifth executable portion configured to provide for a display of a device consumption rate indicator, wherein the display of the device consumption rate indicator changes color based on the device power consumption rate.

16. The computer-readable storage medium of claim 12 further comprising
a fifth executable portion configured to determine at least one supplemental device battery energy level;
a sixth executable portion configured to determine at least one supplemental device power consumption rate from the at least one application power consumption model; and
a seventh executable portion configured to provide for a display of a power indicator, wherein the display of the power indicator alternates between an indication of at least two of the device battery energy level, the device consumption rate, a device charge duration, the at least one supplemental device battery level, and the at least one supplemental device power consumption rate.

17. An apparatus comprising a processor configured to:
access at least one application power consumption model;
determine a device battery energy level; and
determine a device discharge duration using the at least one application power consumption model and the battery energy level.

18. The apparatus of claim 17 wherein the processor is further configured to:
receive a standby discharge duration; and
provide for a notification based on a result of comparing the standby discharge duration to the device discharge duration.

19. The apparatus of claim 17 wherein the processor is further configured to:
determine a device power consumption rate from the at least one application power consumption model; and
provide for a selection of applications to suspend based on a result of comparing the device power consumption rate with a threshold rate.

20. The apparatus of claim 19 wherein the processor is further configured to provide for a display of a device consumption rate indicator, wherein the display of the device consumption rate indicator changes color based on the device power consumption rate.

21. The apparatus of claim 19 wherein the processor is further configured to:
determine at least one supplemental device battery energy level;
determine at least one supplemental device power consumption rate from the at least one application power consumption model; and
provide for a display of a power indicator, wherein the display of the power indicator alternates between an indication of at least two of the device battery energy level, the device consumption rate, a device charge duration, the at least one supplemental device battery level, and the at least one supplemental device power consumption rate.

22. An apparatus comprising:
means for accessing at least one application power consumption model;
means for determining a device battery energy level; and
means for determining a device discharge duration using the at least one application power consumption model and the battery energy level.

23. The apparatus of claim 22 further comprising:
means for receiving a standby discharge duration; and
means for providing for a notification based on a result of comparing the standby discharge duration to the device discharge duration.

24. The apparatus of claim 22 further comprising:
means for determining a device power consumption rate from the at least one application power consumption model; and
means for providing for a selection of applications to suspend based on a result of comparing between the device power consumption rate and a threshold rate.

25. The apparatus of claim 22 further comprising means for providing for a display of a device consumption rate indicator, wherein the display of the device consumption rate indicator changes color based on the device power consumption rate.
